(19) United States
(12) Patent Application Publication
(10) Pub. No.: US 2026/0367128 A1
(43) Pub. Date: Nov. 19, 2026

(54) DETECTING AND LOCATING DEFECTIVE CAPACITORS

(71) Applicant: INTERNATIONAL BUSINESS MACHINES CORPORATION, ARMONK, NY (US)

(72) Inventors: Brian Charles Tucker, Clinton Corners, NY (US); Marc Henri Coq, Hopewell Junction, NY (US); Enver Candan, Cornwall, NY (US)

(21) Appl. No.: 19/210,380

(22) Filed: May 16, 2025

(51) Int. Cl. G01R 31/01; G01R 31/304; G01R 31/52; G01R 31/64

(52) U.S. Cl. CPC G01R 31/016; G01R 31/304; G01R 31/52; G01R 31/64

(57) ABSTRACT

Techniques for detecting and locating a defective capacitor include using a computer to communicate with a device to detect when one or more of a plurality of capacitors emanate a magnetic field meeting a threshold. The device is positioned in space relation over each of the plurality of capacitors, and the device is configured to detect a magnetic field emanating from one or more of the capacitors. Using the computer, a shorted capacitor is flagged when one or more of the capacitors having a magnetic field meeting the threshold.

### BACKGROUND

The present disclosure relates to detecting and locating defective capacitors, and more specifically, detecting and locating defective capacitors coupled to other structures and devices or elements, such as a printed circuit boards (PCBs) or cables.

In one example, a multi-layer ceramic capacitor (MLCC) is a type of capacitors that are used for a wide variety of purposes. These capacitors are used widely in electronic devices due to their low effective series resistance, low-cost, and long lifespan. The primary failure mode of a MLCC is a short-circuit condition caused by an internal fracture of the ceramic dielectric. In one example, an MLCC may be damaged early in its life cycle due to latent defects in the dielectric layer, which is often exacerbated by the heating and cooling cycles that are part of the soldering process. They can also often be damaged from mechanical stress, such as caused by PCB warpage or handling, as well as over tightening or poor placement of mechanical fasteners. The capacitors are often found in large quantities on logic cards as a means of supporting high current with respect to time (dI/dt) (derivative of the current with respect to time) associated with ASIC (application-specific integrated circuit) internal activities. One problem that occurs when a capacitor fails and is in a shorted failure mode of a capacitor, and when combined with the large numbers of capacitors on a single power bus, locating a failed capacitor can be difficult, as the short can be detected as occurring across the entire power boundary.

The present disclosure recognizes the shortcomings and problems associated with detecting failure of capacitors and locating the capacitors coupled to other structures and devices or elements, such as a printed circuit boards (PCBs) or cables.

Embodiments of the invention provide a non-invasive, automatic, solution for detecting a failed capacitor and a location of the failed capacitor in a production environment.

In an aspect according to the present invention, a computer implemented method for detecting and locating a defective capacitor includes detecting, using a computer communicating with a device, when one or more of a plurality of capacitors emanate a magnetic field meeting a threshold. And the detecting and the locating of the defective capacitor is in response to the device being positioned in space relation over each of the plurality of capacitors. The device is configured to detect a magnetic field emanating from one or more of the capacitors, and using the computer, flagging one or more of the capacitors having a magnetic field meeting the threshold.

In a related aspect, the device is a hall effect device.

In a related aspect, the method further including communicating to a computer of an operator, the flagging of the shorted capacitor.

In a related aspect, the method further including communicating to a computer of an operator, the shorted capacitor has been flagged and the communicating including a location of the shorted capacitor.

In a related aspect, the flagging of the shorted capacitor includes identifying one or more of the capacitors having a magnetic field meeting the threshold by a position on the PCB.

In a related aspect, a location of the one or more capacitors on the PCB includes using a grid position on a planar surface having x and y coordinates.

In a related aspect, the device being positioned in spaced relation over each of the plurality of capacitors on the PCB includes locating a hall effect device over the PCB in space relation with each of the plurality of capacitors in sequence, and the capacitors being affixed to the PCB at capacitor locations, respectively.

In a related aspect, the method further including positioning the hall effect device over one or more of the plurality of capacitors.

In a related aspect, the method further including logging a magnitude of a magnetic field around or emanating from each of the one or more capacitors.

In a related aspect, the method further including generating a heatmap indicating the capacitor locations and associated magnetic field strengths.

In a related aspect, the device can detect the presence of magnetic field and produce an analog voltage output that corresponds linearly to the magnitude of the magnetic field.

In a related aspect, the method further including locating a hall effect device in spaced relation and over a plurality of capacitors at capacitor locations, respectively. The method includes positioning, using the computer, the hall effect device over one or more of the plurality of capacitors. The method includes logging, using the computer, a magnitude of a magnetic field around or emanating from each of the one or more capacitors, and generating a heatmap, using the computer, indicating the capacitor locations and associated magnetic field strengths.

In a related aspect, the method further including collecting the magnitude of the magnetic fields for each of the one or more capacitors as collected data; and receiving the collected data at a computer for the generating of the heatmap.

In a related aspect, a PCB is coupled to a fixture and the device is coupled to a moveable tool.

In a related aspect, the method further including hovering the device over each of the capacitors for a period of time.

In a related aspect, the method further including hovering the device over each of the capacitors in a sequence.

In a related aspect, the method further including utilizing X-Y placement data from a manufacturing dataset for a PCB, received at the computer, to control a robotic probe having the device.

In a related aspect, the device can detect a presence of a magnetic field and produce an analog voltage output that corresponds linearly to the magnitude of the magnetic field, and a PCB including the plurality of the capacitors is coupled to a fixture and the device is coupled to a moveable tool. The method further including positioning, using the computer, the hall effect device over one or more of the plurality of capacitors; and collecting the magnitude of the magnetic fields for each of the one or more capacitors as collected data. The method further including receiving the collected data at a computer for generating of a heatmap, and generating the heatmap from the collected data, using the computer, indicating the capacitor locations and associated magnetic field strengths.

In another aspect according to the present invention, a computer system for detecting and locating a defective capacitor, including a processor set, a computer-readable storage medium, and program instructions stored on the computer-readable storage medium to cause the processor set to perform operations as follows. An operation includes detecting, using a computer communicating with a device, when one or more of a plurality of capacitors emanates a magnetic field meeting a threshold, in response to the device being positioned in space relation over each of the plurality of capacitors. The device is configured to detect a magnetic field emanating from one or more of the capacitors. Another operation includes flagging, using the computer, as a shorted capacitor, one or more of the capacitors having a magnetic field meeting the threshold.

In another aspect according to the present invention, a system to detect and locate a defective capacitor which includes a plurality of capacitors coupled to one or more elements. The system includes a tool being configured to move a device in space relation over the capacitors, and the device is configured to detect a magnetic field emanating from one or more of the capacitors. The system includes a computer configured to communicate with the device and the tool. The computer is configured to receive magnetic field data from the device to detect when a magnetic field exceeds a threshold, and the computer is configured to flag one or more of the capacitors when the magnetic field of the one or more capacitors exceeds the threshold, respectively.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. The drawings are discussed forthwith below.

FIG. 1 is a schematic block diagram depicting a top view of a printed circuit board (PCB) including a plurality of capacitors, according to one embodiment of the present disclosure.

FIG. 2 is a schematic block diagram depicting a side elevational view of one of the capacitors shown in FIG. 1., depicting a magnetic field and polarity of the magnetic field.

FIG. 3 is a schematic block diagram depicting a side elevational view of the capacitor and magnetic field shown in FIG. 2, and a magnetic field detection device or component for detecting and locating a defective capacitor on the PCB.

FIG. 4 is a schematic block diagram, according to one embodiment of the present disclosure, of a system for detecting and locating a defective capacitor on the PCB depicting the PCB, magnetic field, and a magnetic field detection device shown in FIG. 3, and further depicting a computer system communicating with the magnetic field detection device and communicating with an exemplary control system via a communications network.

FIG. 5 is a flow chart depicting a method according to one embodiment of the present disclosure, for detecting and locating a defective capacitor using the system shown in FIG. 4.

FIG. 6 is a flow chart depicting additional method steps for detecting and locating a defective capacitor using the system shown in FIG. 4 and the method shown in FIG. 5.

FIG. 7 is a schematic block diagram depicting a computer system according to an embodiment of the disclosure, which includes cloud computing components and functions, and which can cooperate, where applicable, with the one or more apparatuses, systems, and methods shown in the figures and described herein.

### DETAILED DESCRIPTION

The following description with reference to the accompanying drawings is provided to assist in a comprehensive understanding of exemplary embodiments of the invention as defined by the claims and their equivalents. The description includes various specific details to assist in that understanding, but these are to be regarded as merely exemplary, and assist in providing clarity and conciseness. Accordingly, those of ordinary skill in the art will recognize that various changes and modifications of the embodiments described herein can be made without departing from the scope and spirit of the invention. In addition, descriptions of well-known functions and constructions may be omitted.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Embodiments and figures of the present disclosure may have the same or similar components as other embodiments. Such figures and descriptions illustrate and explain further examples and embodiments according to the present disclosure. Embodiments of the present disclosure can include operational actions and/or procedures. A method, such as a computer-implemented method, can include a series of operational blocks for implementing an embodiment according to the present disclosure which can include cooperation with one or more systems shown in the figures. The operational blocks of the methods and systems according to the present disclosure can include techniques, mechanism, modules, and the like for implementing the functions of the operations in accordance with the present disclosure. Similar components may have the same reference numerals. Components can operate in concert with a computer implemented method. It is understood that a user can be a customer, an individual, or a group of individuals, or a company or an organization.

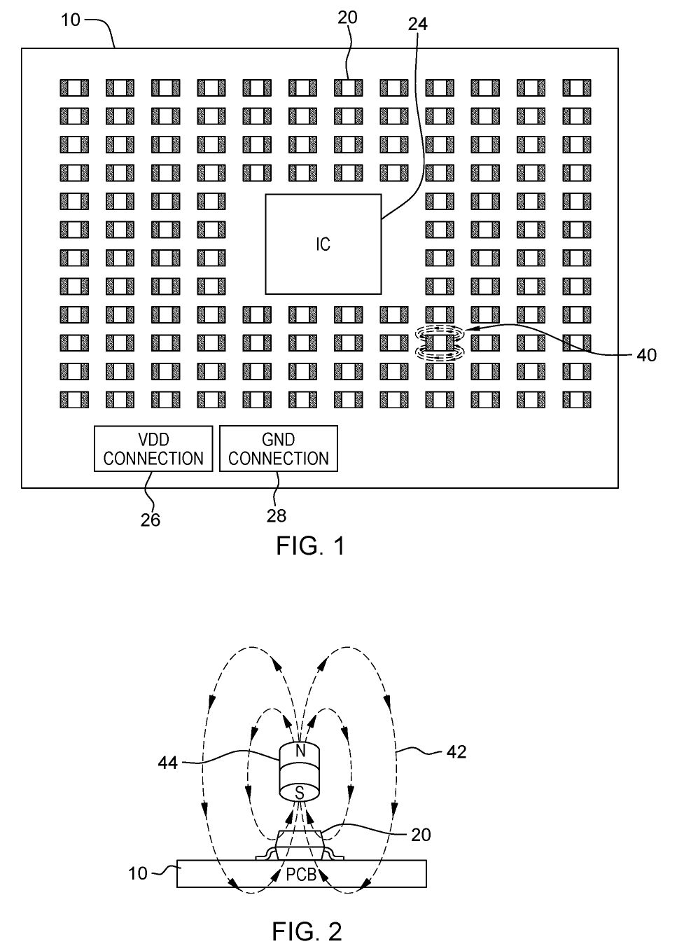

Referring to FIG. 1, according to one embodiment of the present disclosure, a printed circuit board 10 includes a plurality of capacitors 20. An integrated circuit (IC) 24 is in the center area of the PCB. The PCB includes a VDD (Positive Supply Voltage) connection 26 and a GND (Ground) connection 28. A magnetic field 40 is located at one of the capacitors and emanating from the capacitor. For example, the capacitor can be an MLCC (Multi-Layered Ceramic Capacitor).

Although the capacitors are depicted in FIGS. 1, 2,3 and 4, coupled to a PCB, embodiments of the present disclosure can be applied to capacitors coupled to other devices and elements, such as cables. The array of capacitors on a PCB is but one embodiment of various embodiments of applications of the techniques described in the present disclosure.

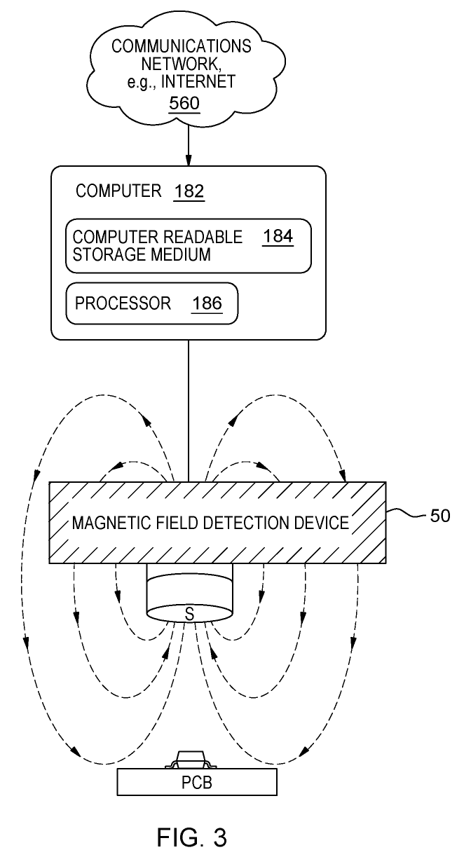

Referring to FIGS. 2 and 3, in one example, the magnetic field 40 is shown as magnetic field lines 42 of a magnet 44 having polarity. A magnetic field detection device or component 50 (FIG. 3) positioned over the capacitor 20 detects the magnetic field represented by the magnetic field line 42.

The printed circuit board can be a multilayer type of board with interleaved power and ground planes. The PCB can be a single power boundary. If one of the capacitors fails, that is, shorted out in an array of capacitors, a test voltage is applied across VDD 26 and the ground connection 28. The test voltage is low to prevent activation of any logic. The current source is strong enough to allow for detection of a magnetic field. Current flow through the PCB can produce a magnetic field, typically a small magnetic field, as the field may be cancelled due to the lamination of the power and ground planes. A magnetic field can be produced in the vicinity of a failed capacitor as the current comes up out of the board, flows through the capacitor, and returns to the board.

A hall-effect device is a semiconductor product that can detect the presence of a magnetic field and produce an analog voltage output that corresponds linearly to the magnitude of the magnetic field. In one example, the device is attached to a movable robotic head, which can be similar to that used in a flying probe type inspection machine. The X-Y placement data from the PCB manufacturing dataset can be utilized to control the probe. In one example, the probe hovers directly over each MLCC locations, and logs the magnitude of the magnetic field at each location. The collected data can be formatted as a heatmap, and the heatmap indicates the locations at which the greatest field strength was found. A shorted capacitor will be the capacitor to have a magnetic field associated with it. In contrast, good (or not shorted or not failed) capacitors will have no current flow associated with them once they have reached a steady-state.

Embodiments of the present disclosure can detect one or more shorted MLCC capacitors in an automated production environment. A hall-effect type sensor can be employed for magnetic field sensing, indicating areas of high current flow. Pick-and-place X-Y data utilized to pinpoint capacitor locations. Automated equipment can be used to measure a magnetic field at each prescribed location. Aggregated data can be presented as a heat map to a rework operator in order to pinpoint one or more bad capacitors.

In one embodiment, the magnetic field detection device according to techniques described herein, can be used as a standalone, hand-held, device. The detection device may be used to augment manufacturing testing, and the detection device may be used to troubleshoot field installations. Similarly, embodiment according to the present disclosure may be used to detect shorts in other components, for example, integrated circuits, tantalum capacitors, shorted PCB elements (e.g. cracked, shorted, vias), and unintentional solder bridges.

Embodiments of the present disclosure include a method of detecting component failure on a component-by-component basis. The method includes pinpointing the location of a component that has failed in an electrically shorted fashion, thus emitting a magnetic field when a test current is supplied to the assembly. Additionally, pick-and-place manufacturing data can be utilized to supply location information/coordinates to an automated probing process that can observe and report the absolute magnetic field strength at each component location. Thereby, a map can be produced showing where the unexpected field, as well as the failed component, is located. Thus, the method improves the detection accuracy of the defective component. Further, the method greatly decreases the time required to troubleshoot capacitor defects with precision, and thereinafter repair in an environment with large PCB assemblies that contain large arrays of MLCCs.

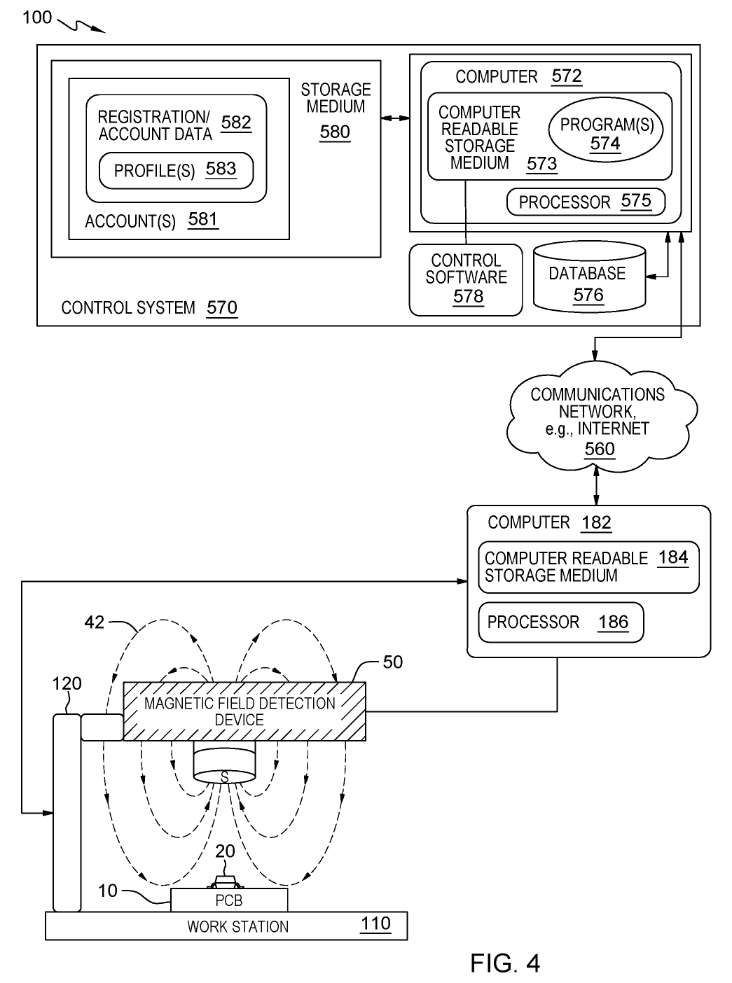

Referring to FIG. 4, a system 100 according to an embodiment of the present disclosure includes the PCB 10 including a capacitor 20 emanating a magnetic field depicted by magnetic field lines 42 and the magnet 44. The magnetic field is detected using the magnetic field detection device. In one example, the magnetic field detection device (also referred to as a detection device) can be a hall-effect device or sensor. The detection device communicates with a computer 182. The computer 182 includes a computer readable storage medium 184 and a processor 186. The detection device can communicate with the computer as a component of the device, a communications cable, or a wireless communication protocol. The computer 182 can also communicate with a control system via a communications network 560, e.g., the Internet.

Further referring to FIG. 4, the PCB can be situated on a workstation 110, and a tool 120 is connected at one end to the workstation and at a distal end to the magnetic field detection device 50. In one example the tool is an articulated arm which is configured to move the detection device over each of the capacitors on the PCB. In one example, the movement of the arm be controlled by the computer 182.

The control system 570 includes a computer 572 which can be integral with or communicating with a device, and communicates with other computers such as the computer 182. The control system 570 can include the computer 572 having a computer readable storage medium 573 which can store one or more programs 574 embedded on the storage medium, and a processor 575 for executing program instructions. The control system 570 can include control software 578 for managing the one or more programs. The control system can also include a storage medium which can include registration and/or account data 582 and user profiles 583 of users or entities (such entities can include robotic entities) as part of user accounts 581. User accounts 581 can be stored on a storage medium 580 which is part of the control system 570. The user accounts 581 can include registrations and account data 582 and user profiles 583. The program code can be executed by a processor 575. The computer 572 can communicate with a database 576 for storing all or part of data as described above, and data regarding machines and robots.

In one example, the control system can assist or provide control of the detection device 50. In one example, as shown in FIG. 4, the computer 182 communicates with the remote computer 572 via the communications network 560. The control system 570 can manage the implementation of the detection device by moving and positioning the detection device of each of the capacitors on the PCB. The control system can be local, e.g., at a work venue with the PCB, or remote, such as a cloud-based system or at a remote location communicating using the communications network 560 such as the Internet.

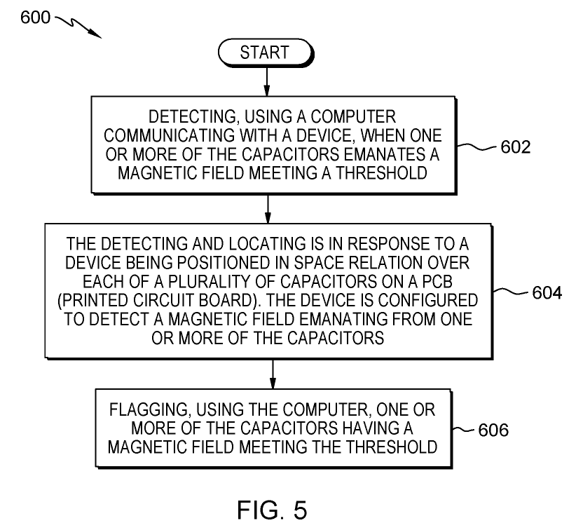

Referring to FIG. 5, with reference to the system 100 shown in FIG. 4, a method 600 for detecting and locating a defective capacitor includes detecting, using a computer 182 communicating with a device, such as the magnetic field detection device 50, when one or more of a plurality of capacitors 20 emanates a magnetic field 40 meeting a threshold, as in operation 602. The detecting and locating is in response to the device 50 positioned in space relation over each of the plurality of capacitors 20. In one example, the capacitors can be coupled to a PCB 10 (printed circuit board). The device 50 is configured to detect the magnetic field 40 emanating from one or more of the capacitors 20, as in operation 604.

The method 600 includes flagging, using the computer, one or more capacitors as having a magnetic field strength meeting the threshold, as in operation 606, and which can be measured using a Hall effect sensor or device. The threshold can indicate that the capacitor does not meet a standard (or measurement or threshold) for storing electrical energy, and thus may be leaking, or otherwise have a less than desired electrical storage capacity, i.e., that does not meet an energy storage threshold, and thus meets a threshold of emanating a magnetic field. A capacitor meeting the threshold for a magnetic field may also be considered a shorted capacitor, depending on a setting of the threshold. For instance, a low threshold may indicate a leaky capacitor not meeting a standard for storing electrical energy, and a higher threshold can indicate a shorted capacitor. Thereby, various thresholds can indicate respective levels of capacitor effectiveness or ineffectiveness as measured by their electrical energy storage capacity, for example, as measured in Joules.

In one example, the method can include positioning a device in spaced relation over each of a plurality of capacitors on a PCB. The device detects a magnetic field emanating from one or more of the capacitors.

In one example, the device (magnetic field detection device) is a hall effect device.

In another example, the method can further include communicating the flagging of the shorted capacitor to a computer of an operator.

In another example, the method further includes communicating to a computer of an operator, the shorted capacitor which was flagged, and the communicating including a location of the shorted capacitor on the PCB.

In another example, the flagging of the shorted capacitor includes identifying one or more of the capacitors having a magnetic field meeting the threshold by a position on the PCB.

In another example, a location of the one or more capacitors on the PCB includes using a grid position on a planar surface having x and y coordinates.

In another example, the device is positioned in spaced relation over each of the plurality of capacitors on the PCB includes locating a hall effect device over the PCB in space relation with each of the plurality of capacitors in sequence, and the capacitors being affixed to the PCB at capacitor locations, respectively.

In another example, the method includes positioning the hall effect device over one or more of the plurality of capacitors.

In another example, the method further includes logging a magnitude of a magnetic field around or emanating from each of the one or more capacitors.

In another example, the method further includes generating a heatmap indicating the capacitor locations and associated magnetic field strengths.

In another example, the device can detect the presence of magnetic field and produce an analog voltage output that corresponds linearly to the magnitude of the magnetic field.

In another example, the capacitor is a ceramic material.

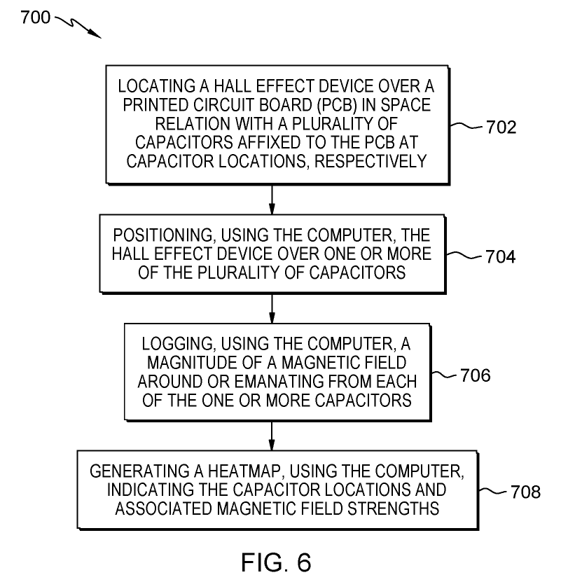

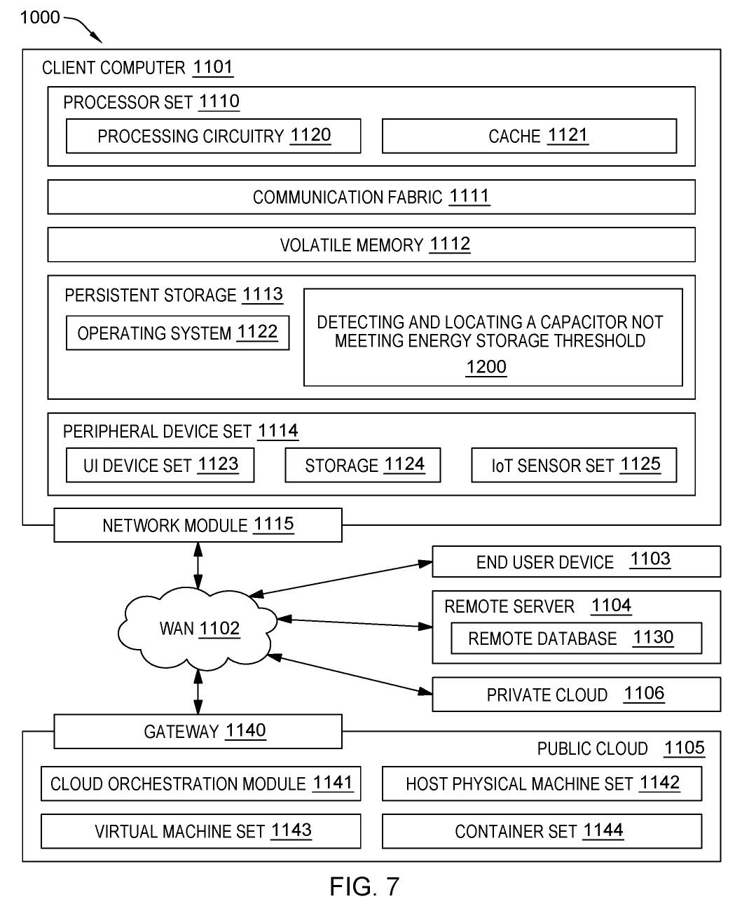

Referring to FIG. 7, in another example, the method 700 shown in FIG. 6, further includes locating a hall effect device over a printed circuit board (PCB) in space relation with a plurality of capacitors affixed to the PCB at capacitor locations, respectively, as in operation 702. The method further includes positioning, using the computer, the hall effect device over one or more of the plurality of capacitors, as in operation 704. The method includes logging, using the computer, a magnitude of a magnetic field around or emanating from each of the one or more capacitors, as in operation 706. The method includes generating a heatmap, using the computer, indicating the capacitor locations and associated magnetic field strengths, as in operation 708.

In another example, the method further includes collecting the magnitude of the magnetic fields for each of the one or more capacitors as collected data; and receiving the collected data at a computer for the generating of the heatmap.

In another example, the PCB is coupled to a fixture and the device is coupled to a moveable tool. In one example, the movable tool is a robotic head.

In another example, the method includes hovering the device over each of the capacitors for a period of time.

In another example, the method includes hovering the device over each of the capacitors in a sequence.

In another example, the method includes utilizing X-Y placement data from a manufacturing dataset for the PCB, received at the computer, to control a robotic probe having the device.

In another example, the device can detect a presence of a magnetic field and produce an analog voltage output that corresponds linearly to the magnitude of the magnetic field. In one example, the PCB is coupled to a fixture and the device is coupled to a moveable tool. The method can include positioning, using the computer, the hall effect device over one or more of the plurality of capacitors. The method further includes collecting the magnitude of the magnetic fields for each of the one or more capacitors as collected data. The method further including receiving the collected data at a computer for the generating of a heatmap; and generating the heatmap from the collected data, using the computer, indicating the capacitor locations and associated magnetic field strengths.

In one embodiment according to the disclosure, a computer system for detecting and locating a defective capacitor includes a processor set, a computer-readable storage medium, and program instructions stored on the computer-readable storage medium to cause the processor set to perform operations as recited herein. The computer system includes operations for detecting, using a computer communicating with a device, when one or more of the capacitors emanates a magnetic field meeting a threshold, in response to a device being positioned in space relation over each of a plurality of capacitors on a PCB (printed circuit board). The device is configured to detect a magnetic field emanating from one or more of the capacitors. The computer system includes operations for flagging, using the computer, as a shorted capacitor, one or more of the capacitors having a magnetic field meeting the threshold.

In one embodiment according to the disclosure, a system to detect and locate a defective capacitor includes a PCB board having a plurality of capacitors coupled thereto. A tool being configured to move a device in space relation over the capacitors. The device being configured to detect a magnetic field emanating from one or more of the capacitors. The system further includes a computer which is configured to communicate with the device and the tool. The computer is configured to receive magnetic field data from the device to detect when a magnetic field exceeds a threshold, and the computer is configured to flag one or more of the capacitors when the magnetic field of the one or more capacitors exceeds the threshold, respectively.

In another embodiment according to the present disclosure, a computer program product for detecting and locating a defective capacitor includes a computer readable storage medium, and program instructions stored on the computer readable storage medium to perform operations including the operations below.

One operation includes detecting, using a computer communicating with a device, when one or more of a plurality of capacitors emanates a magnetic field meeting a threshold, and in response to the device positioned in space relation over each of the plurality of capacitors on a PCB (printed circuit board). The device is configured to detect a magnetic field emanating from one or more of the capacitors.

Another operation includes flagging, using the computer, as a shorted capacitor, one or more of the capacitors having a magnetic field meeting the threshold.

In other embodiments and examples, in the present disclosure shown in the figures, a computer can be part of a remote computer or a remote server, for example, a remote server. In another example, the computer can be part of a control system and provide execution of the functions of the present disclosure. In another embodiment, a computer can be part of a mobile device and provide execution of the functions of the present disclosure. In still another embodiment, parts of the execution of functions of the present disclosure can be shared between the control system computer and the mobile device computer, for example, the control system function as a back end of a program or programs embodying the present disclosure and the mobile device computer functioning as a front end of the program or programs. A device(s), for example a mobile device or mobile phone, can belong to one or more users, and can be in communication with the control system via the communications network.

Methods and systems according to embodiments of the present disclosure, can be incorporated in one or more computer programs or an application stored on an electronic storage medium, and executable by the processor, as part of the computer on mobile device. For example, a mobile device can communicate with the control system, and in another example, a device such as a video feed device can communicate directly with the control system. Other users (not shown) may have similar mobile devices which communicate with the control system similarly. The application can be stored, all or in part, on a computer or a computer in a mobile device and at a control system communicating with the mobile device, for example, using the communications network, such as the Internet. It is envisioned that the application can access all or part of program instructions to implement the method of the present disclosure. The program or application can communicate with a remote computer system via a communications network (e.g., the Internet) and access data, and cooperate with program(s) stored on the remote computer system. Such interactions and mechanisms are described in further detail herein and referred to regarding components of a computer system, such as computer readable storage media, which are shown in one or more embodiments herein and described in more detail in regards thereto referring to one or more computers and systems described herein.

In another example and embodiment, profiles can be saved for entities such as users, participants, operators, human operators, or robotic devices. Such profiles can supply data regarding the user and history of deliveries for analysis. In one example, a user can register or create an account using the control system which can include one or more profiles as part of registration and/or account data. The registration can include profiles for each user having personalized data. For example, users can register using a website via their computer and GUI (Graphical User Interface) interface. The registration or account data can include profiles for an account for each user. Such accounts can be stored on the control system, which can also use the database for data storage. A user and a related account can refer to, for example, a person, an administrator, or an operator, or an entity, or a corporate entity, or a corporate department, or another machine such as an entity for automation such as a system using, in all or in part, artificial intelligence.

Account data, for instance, including profile data related to a user, and any data, personal or otherwise, can be collected and stored, for example, in a control system. It is understood that such data collection is done with the knowledge and consent of a user, and stored to preserve privacy, which is discussed in more detail below. Such data can include personal data, and data regarding personal items. In one example a user can register and have an account with a user profile on a control system. For example, data can be collected using techniques as discussed above, for example, using cameras, and data can be uploaded to a user profile by the user. A user can include, for example, a corporate entity, or department of a business, or a homeowner, or any end user, a human operator, or a robotic device, or other personnel of a business.

It is also understood that methods and systems according to embodiments of the present disclosure, can be incorporated into (Artificial Intelligence) AI devices, components or be part of an AI system, which can communicate with respective AI systems and components, and respective AI system platforms. Thereby, such programs or an application incorporating the method of the present disclosure, as discussed above, can be part of an AI system. In one embodiment according to the present invention, it is envisioned that the control system can communicate with an AI system, or in another example can be part of an AI system. The control system can also represent a software application having a front-end user part and a back-end part providing functionality, which can in one or more examples, interact with, encompass, or be part of larger systems, such as an AI system. In one example, an AI device can be associated with an AI system, which can be all or in part, a control system and/or a content delivery system, and be remote from an AI device. Such an AI system can be represented by one or more servers storing programs on computer readable medium which can communicate with one or more AI devices. The AI system can communicate with the control system, and in one or more embodiments, the control system can be all or part of the AI system or vice versa.

Additionally, methods and systems according to embodiments of the present disclosure can be discussed in relation to a functional system(s) depicted by functional block diagrams. The methods and systems can include components and operations for embodiments according to the present disclosure, and is used herein for reference when describing the operational steps of the methods and systems of the present disclosure. Additionally, the functional system, according to an embodiment of the present disclosure, depicts functional operations indicative of the embodiments discussed herein.

The methods and systems of the present disclosure can include a series of operational blocks for implementing one or more embodiments according to the present disclosure. A method shown in the figures may be another example embodiment, which can include aspects/operations shown in another figure and discussed previously, but can be reintroduced in another example. Thus, operational blocks and system components shown in one or more of the figures may be similar to operational blocks and system components in other figures. The diversity of operational blocks and system components depict example embodiments and aspects according to the present disclosure. For example, methods shown are intended as example embodiments which can include aspects/operations shown and discussed previously in the present disclosure, and in one example, continuing from a previous method shown in another flow chart.

It is understood that the features shown in some of the figures, for example block diagrams, are functional representations of features of the present disclosure. Such features are shown in embodiments of the systems and methods of the present disclosure for illustrative purposes to clarify the functionality of features of the present disclosure.

The descriptions of the various embodiments of the present invention have been

It is also understood that the one or more computers or computer systems shown in the figures can include all or part of a computing environment and its components shown in another figure, for example, the computing environment 1000 can be incorporated, in all or in part, in one or more computers or devices shown in other figures and described herein, or vice versa. In one example, the one or more computers can communicate with all or part of a computing environment and its components as a remote computer system to achieve computer functions described in the present disclosure.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Referring to FIG. 7, a computing environment 1000 contains an example of an environment for the execution of at least some of the computer code involved in performing the inventive methods, such as using a computer for detecting and locating a capacitor not meeting an energy storage threshold, as in block 1200. In addition to block 1200, computing environment 1000 includes, for example, computer 1101, wide area network (WAN) 1102, end user device (EUD) 1103, remote server 1104, public cloud 1105, and private cloud 1106. In this embodiment, computer 1101 includes processor set 1110 (including processing circuitry 1120 and cache 1121), communication fabric 1111, volatile memory 1112, persistent storage 1113 (including operating system 1122 and block 1200, as identified above), peripheral device set 1114 (including user interface (UI), device set 1123, storage 1124, and Internet of Things (IoT) sensor set 1125), and network module 1115. Remote server 1104 includes remote database 1130. Public cloud 1105 includes gateway 1140, cloud orchestration module 1141, host physical machine set 1142, virtual machine set 1143, and container set 1144.

COMPUTER 1101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1130. As is well understood in the art of computer technology, and depending upon the technology, performance of a computer-implemented method may be distributed among multiple computers and/or between multiple locations. On the other hand, in this presentation of computing environment 1000, detailed discussion is focused on a single computer, specifically computer 1101, to keep the presentation as simple as possible. Computer 1101 may be located in a cloud, even though it is not shown in a cloud in FIG. 7. On the other hand, computer 1101 is not required to be in a cloud except to any extent as may be affirmatively indicated.

PROCESSOR SET 1110 includes one, or more, computer processors of any type now known or to be developed in the future. Processing circuitry 1120 may be distributed over multiple packages, for example, multiple, coordinated integrated circuit chips. Processing circuitry 1120 may implement multiple processor threads and/or multiple processor cores. Cache 1121 is memory that is located in the processor chip package(s) and is typically used for data or code that should be available for rapid access by the threads or cores running on processor set 1110. Cache memories are typically organized into multiple levels depending upon relative proximity to the processing circuitry. Alternatively, some, or all, of the cache for the processor set may be located “off chip.” In some computing environments, processor set 1110 may be designed for working with qubits and performing quantum computing.

Computer readable program instructions are typically loaded onto computer 1101 to cause a series of operational steps to be performed by processor set 1110 of computer 1101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1121 and the other storage media discussed below. The program instructions, and associated data, are accessed by processor set 1110 to control and direct performance of the inventive methods. In computing environment 1000, at least some of the instructions for performing the inventive methods may be stored in block 1200 in persistent storage 1113.

COMMUNICATION FABRIC 1111 is the signal conduction paths that allow the various components of computer 1101 to communicate with each other. Typically, this fabric is made of switches and electrically conductive paths, such as the switches and electrically conductive paths that make up busses, bridges, physical input / output ports and the like. Other types of signal communication paths may be used, such as fiber optic communication paths and/or wireless communication paths.

VOLATILE MEMORY 1112 is any type of volatile memory now known or to be developed in the future. Examples include dynamic type random access memory (RAM) or static type RAM. Typically, the volatile memory is characterized by random access, but this is not required unless affirmatively indicated. In computer 1101, the volatile memory 1112 is located in a single package and is internal to computer 1101, but, alternatively or additionally, the volatile memory may be distributed over multiple packages and/or located externally with respect to computer 1101.

PERSISTENT STORAGE 1113 is any form of non-volatile storage for computers that is now known or to be developed in the future. The non-volatility of this storage means that the stored data is maintained regardless of whether power is being supplied to computer 1101 and/or directly to persistent storage 1113. Persistent storage 1113 may be a read only memory (ROM), but typically at least a portion of the persistent storage allows writing of data, deletion of data and re-writing of data. Some familiar forms of persistent storage include magnetic disks and solid state storage devices. Operating system 1122 may take several forms, such as various known proprietary operating systems or open source Portable Operating System Interface type operating systems that employ a kernel. The code included in block 1200 typically includes at least some of the computer code involved in performing the inventive methods.

PERIPHERAL DEVICE SET 1114 includes the set of peripheral devices of computer 1101. Data communication connections between the peripheral devices and the other components of computer 1101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1123 may include components such as a display screen, speaker, microphone, wearable devices (such as goggles and smart watches), keyboard, mouse, printer, touchpad, game controllers, and haptic devices. Storage 1124 is external storage, such as an external hard drive, or insertable storage, such as an SD card. Storage 1124 may be persistent and/or volatile. In some embodiments, storage 1124 may take the form of a quantum computing storage device for storing data in the form of qubits. In embodiments where computer 1101 is required to have a large amount of storage (for example, where computer 1101 locally stores and manages a large database) then this storage may be provided by peripheral storage devices designed for storing very large amounts of data, such as a storage area network (SAN) that is shared by multiple, geographically distributed computers. IoT sensor set 1125 is made up of sensors that can be used in Internet of Things applications. For example, one sensor may be a thermometer and another sensor may be a motion detector.

NETWORK MODULE 1115 is the collection of computer software, hardware, and firmware that allows computer 1101 to communicate with other computers through WAN 1102. Network module 1115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1115 are performed on the same physical hardware device. In other embodiments (for example, embodiments that utilize software-defined networking (SDN)), the control functions and the forwarding functions of network module 1115 are performed on physically separate devices, such that the control functions manage several different network hardware devices. Computer readable program instructions for performing the inventive methods can typically be downloaded to computer 1101 from an external computer or external storage device through a network adapter card or network interface included in network module 1115.

WAN 1102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 1103 is any computer system that is used and controlled by an end user (for example, a customer of an enterprise that operates computer 1101), and may take any of the forms discussed above in connection with computer 1101. EUD 1103 typically receives helpful and useful data from the operations of computer 1101. For example, in a hypothetical case where computer 1101 is designed to provide a recommendation to an end user, this recommendation would typically be communicated from network module 1115 of computer 1101 through WAN 1102 to EUD 1103. In this way, EUD 1103 can display, or otherwise present, the recommendation to an end user. In some embodiments, EUD 1103 may be a client device, such as thin client, heavy client, mainframe computer, desktop computer and so on.

REMOTE SERVER 1104 is any computer system that serves at least some data and/or functionality to computer 1101. Remote server 1104 may be controlled and used by the same entity that operates computer 1101. Remote server 1104 represents the machine(s) that collect and store helpful and useful data for use by other computers, such as computer 1101. For example, in a hypothetical case where computer 1101 is designed and programmed to provide a recommendation based on historical data, then this historical data may be provided to computer 1101 from remote database 1130 of remote server 1104.

PUBLIC CLOUD 1105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1105 is performed by the computer hardware and/or software of cloud orchestration module 1141. The computing resources provided by public cloud 1105 are typically implemented by virtual computing environments that run on various computers making up the computers of host physical machine set 1142, which is the universe of physical computers in and/or available to public cloud 1105. The virtual computing environments (VCEs) typically take the form of virtual machines from virtual machine set 1143 and/or containers from container set 1144. It is understood that these VCEs may be stored as images and may be transferred among and between the various physical machine hosts, either as images or after instantiation of the VCE. Cloud orchestration module 1141 manages the transfer and storage of images, deploys new instantiations of VCEs and manages active instantiations of VCE deployments. Gateway 1140 is the collection of computer software, hardware, and firmware that allows public cloud 1105 to communicate through WAN 1102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 1106 is similar to public cloud 1105, except that the computing resources are only available for use by a single enterprise. While private cloud 1106 is depicted as being in communication with WAN 1102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1105 and private cloud 1106 are both part of a larger hybrid cloud.

What is claimed is:

1. A computer implemented method for detecting and locating a defective capacitor, comprising:
detecting, using a computer communicating with a device, when one or more of a plurality of capacitors emanate a magnetic field meeting a threshold, in response to the device being positioned in space relation over each of the plurality of capacitors, the device being configured to detect a magnetic field emanating from one or more of the capacitors; and
flagging, using the computer, one or more of the capacitors having a magnetic field meeting the threshold.

2. The method of claim 1, wherein the device is a hall effect device.

3. The method of claim 1, further comprising:
communicating to a computer of an operator, the flagging of the one or more capacitors.

4. The method of claim 1, further comprising:
communicating to a computer of an operator, the one or more capacitors which are flagged, and the communicating including a location of the shorted capacitor.

5. The method of claim 1, wherein the flagging of the shorted capacitor includes identifying one or more of the capacitors having a magnetic field meeting the threshold by a position on a PCB (Printed Circuit Board).

6. The method of claim 1, wherein a location of the one or more capacitors on a PCB includes using a grid position on a planar surface having x and y coordinates.

7. The method of claim 1, wherein the device being positioned in spaced relation over each of the plurality of capacitors on a PCB includes locating a hall effect device over the PCB in space relation with each of the plurality of capacitors in sequence, and the capacitors being affixed to the PCB at capacitor locations, respectively.

8. The method of claim 1, further comprising:
positioning the hall effect device over one or more of the plurality of capacitors.

9. The method of claim 1, further comprising:
logging a magnitude of a magnetic field around or emanating from each of the one or more capacitors.

10. The method of claim 1, further comprising:
generating a heatmap indicating the capacitor locations and associated magnetic field strengths.

11. The method of claim 1, wherein the device can detect the presence of magnetic field and produce an analog voltage output that corresponds linearly to the magnitude of the magnetic field.

12. The method of claim 1, further comprising:
locating a hall effect device in space relation and over a plurality of capacitors at capacitor locations, respectively;
positioning, using the computer, the hall effect device over one or more of the plurality of capacitors;
logging, using the computer, a magnitude of a magnetic field around or emanating from each of the one or more capacitors; and
generating a heatmap, using the computer, indicating the capacitor locations and associated magnetic field strengths.

13. The method of claim 1, further comprising:
collecting the magnitude of the magnetic fields for each of the one or more capacitors as collected data; and
receiving the collected data at a computer for the generating of the heatmap.

14. The method of claim 1, wherein a PCB including the plurality of capacitors is coupled to a fixture and the device is coupled to a moveable tool.

15. The method of claim 1, further comprising:
hovering the device over each of the capacitors for a period of time.

16. The method of claim 1, further comprising:
hovering the device over each of the capacitors in a sequence.

17. The method of claim 1, further comprising:
utilizing X-Y placement data from a manufacturing dataset for a PCB, received at the computer, to control a robotic probe having the device.

18. The method of claim 1, wherein the device can detect a presence of a magnetic field and produce an analog voltage output that corresponds linearly to the magnitude of the magnetic field; and
wherein a PCB including the plurality of the capacitors is coupled to a fixture and the device is coupled to a moveable tool;
the method further comprising:
positioning, using the computer, the hall effect device over one or more of the plurality of capacitors;
collecting the magnitude of the magnetic fields for each of the one or more capacitors as collected data;
receiving the collected data at a computer for generating of a heatmap; and
generating the heatmap from the collected data, using the computer, indicating the capacitor locations and associated magnetic field strengths.

19. A computer system for detecting and locating a defective capacitor, comprising:
a processor set, a computer-readable storage medium, and program instructions stored on the computer-readable storage medium to cause the processor set to perform operations, comprising:
detecting, using a computer communicating with a device, when one or more of a plurality of capacitors emanates a magnetic field meeting a threshold, in response to the device being positioned in space relation over each of the plurality of capacitors, the device being configured to detect a magnetic field emanating from one or more of the capacitors; and
flagging, using the computer, as a shorted capacitor, one or more of the capacitors having a magnetic field meeting the threshold.

20. A system to detect and locate a defective capacitor, which comprises:
a plurality of capacitors coupled to one or more elements;
a tool being configured to move a device in space relation over the plurality of capacitors, respectively, the device being configured to detect a magnetic field emanating from one or more of the plurality of capacitors; and
a computer being configured to communicate with the device and the tool, the computer being configured to receive magnetic field data from the device to detect when a magnetic field exceeds a threshold, and the computer being configured to flag one or more of the capacitors when the magnetic field of the one or more capacitors exceeds the threshold, respectively.
